(19) United States
(12) Patent Application Publication
(10) Pub. No.: US 2024/0321677 A1
(43) Pub. Date: Sep. 26, 2024

(54) SEMICONDUCTOR DEVICES WITH THERMOELECTRIC COOLER

(71) Applicant: Texas Instruments Incorporated, Dallas, TX (US)

(72) Inventors: Jingjing Chen, San Jose, CA (US); Archana Venugopal, Mountain View, CA (US)

(21) Appl. No.: 18/397,476

(22) Filed: Dec. 27, 2023

Related U.S. Application Data
(60) Provisional application No. 63/492,070, filed on Mar. 24, 2023.

(51) Int. Cl. H01L 23/38; H01L 23/532; H01L 29/78

(52) U.S. Cl. CPC H01L 23/38; H01L 23/53209; H01L 29/7824

(57) ABSTRACT

Semiconductor devices including thermoelectric coolers and method of operating the semiconductor devices are described. A semiconductor device includes an SOI substrate with one or more components (e.g., a transistor) generating heat during operation. The semiconductor device includes a thermoelectric cooler surrounding the transistor. The thermoelectric cooler includes a first electrode laterally surrounding the transistor, a holey silicon region laterally surrounding and contacting the first electrode, and a second electrode laterally surrounding and contacting the holey silicon region. The thermoelectric cooler, when activated, can reduce operating temperature of the transistor. In some cases, pre-cooling may be done to further reduce the operating temperature.

### CROSS-REFERENCE TO RELATED APPLICATIONS

This application claims the benefit of U.S. Provisional Patent Application No. 63/492,070, entitled “Thermoelectric Cooler with Through-Si Trenches/Holes for Silicon-on-Insulator (SOI) Devices,” filed Mar. 24, 2023, the content of which is hereby incorporated by reference in its entirety herein.

### TECHNICAL FIELD

The present disclosure relates to the field of semiconductor devices, and more particularly to semiconductor devices with thermoelectric coolers.

### BACKGROUND

Certain semiconductor devices (e.g., power transistors) generate heat during their operation and managing thermal energy emanating from the semiconductor devices is challenging. Power transistors using semiconductor-on-insulator (SOI) technique provide excellent electrical characteristics when compared to power transistors built in a bulk substrate, such as lower parasitic capacitance due to isolation from the bulk substrate, resistance to latch-up phenomena due to completely isolated n-well and p-well structures, and lower leakage current characteristics, among others. The power transistors built in SOI substrates, however, face challenges associated with weaker thermal dissipation as the heat tends to be confined in a relatively thin semiconductor layer, instead of having access to the bulk substrate to dissipate the heat.

### SUMMARY

The present disclosure describes semiconductor devices that include semiconductor thermoelectric coolers. This summary is not an extensive overview of the disclosure. Rather, the primary purpose of the summary is to present some concepts of the disclosure in a simplified form as a prelude to a more detailed description that is presented later.

In some examples, a semiconductor device includes a substrate including a dielectric layer and a semiconductor layer on the dielectric layer, a first electrode laterally surrounding a first region of the semiconductor layer, a second region of the semiconductor layer laterally surrounding and contacting the first electrode, and a second electrode laterally surrounding and contacting the second region of the semiconductor layer.

In some examples, a semiconductor device includes a substrate including a dielectric layer and a semiconductor layer on the dielectric layer, an array of first electrodes, each of the first electrode laterally surrounding a respective first region of the semiconductor layer, a second region of the semiconductor layer laterally surrounding and contacting each of the first electrode of the array, and a second electrode laterally surrounding and contacting the second region of the semiconductor layer.

In some examples, a method includes applying an electrical bias to a first electrode laterally surrounding a first region of a semiconductor layer, the first region including one or more semiconductor components generating heat during operation, and activating the one or more semiconductor components after applying the electrical bias to the first electrode, where the semiconductor layer is disposed on an oxide layer of a substrate, a second region of the semiconductor layer laterally surrounding and contacting the first electrode, and a second electrode laterally surrounding and contacting the second region of the semiconductor layer.

### BRIEF DESCRIPTION OF THE DRAWINGS

FIGS. 1A through 1D illustrate aspects of a semiconductor device with a thermoelectric cooler in an example of the description;

FIGS. 2A and 2B illustrate plan view diagrams of semiconductor devices with thermoelectric coolers in examples of the description;

FIGS. 3A through 3C illustrate diagrams of operating characteristics of a semiconductor device with a thermoelectric cooler in examples of the description;

FIGS. 4A through 4C illustrate aspects of arrays of semiconductor devices with thermoelectric coolers in examples of the description; and

FIGS. 5A through 5C illustrate diagrams of operating characteristics of an array of semiconductor devices with thermoelectric coolers in examples of the description.

### DETAILED DESCRIPTION

The present disclosure is described with reference to the attached figures. The components in the figures are not drawn to scale. Instead, emphasis is placed on clearly illustrating overall features and the principles of the present disclosure. Numerous specific details and relationships are set forth with reference to examples of the figures to provide an understanding of the disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in the semiconductor devices in view of the orientation shown in the figures. For example, “upper” or “uppermost” can refer to a feature positioned closer to the top of a page than other features. The terms so used are interchangeable under appropriate circumstances such that the examples of the technology described herein are, for example, capable of operation in other orientations than those illustrated or otherwise described herein. In the following discussion and in the claims, the terms “including”, “includes”, “having”, “has”, “with”, or variants thereof are intended to be inclusive in a manner similar to the term “comprising”, and thus should be interpreted to mean “including, but not limited to”. Unless otherwise stated, “about,” “approximately,” or “substantially” preceding a value means +/−10 percent of the stated value in some examples. In some examples, “about,” “approximately,” or “substantially” preceding a value means +/−20 percent of the stated value.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

Increasing demand for high-performance semiconductor devices makes it attractive to fabricate semiconductor components (e.g., transistors) in a semiconductor-on-insulator (SOI) substrate. An SOI substrate includes a dielectric layer (e.g., an oxide layer) on a bulk semiconductor substrate and a semiconductor layer on the dielectric layer. In some examples, the semiconductor layer is a silicon layer, and may be referred to as a silicon epitaxial layer, silicon epi-layer, a device layer, or the like. The dielectric layer may be deemed “buried” underneath the semiconductor layer, and may be referred to as a buried oxide (BOX) layer. Transistors built in an SOI substrate (e.g., in the semiconductor layer of the SOI substrate) may be referred to as SOI transistors (or SOI-based devices). The BOX layer separates the semiconductor layer from the bulk semiconductor substrate, and SOI transistors may have reduced leakage current and enhanced electrostatic characteristics (e.g., reduced parasitic capacitance) at least partly due to the separation, resulting in higher switching speed and lower power consumption when compared to similar transistors built in a bulk semiconductor substrate. However, the dielectric layer has poor thermal conduction characteristics, which may impede thermal dissipation of the heat generated in the SOI transistors, and may cause self-heating issues.

The present disclosure relates generally, but not exclusively, to facilitating heat dissipation for semiconductor components built in SOI substrates (e.g., SOI transistors, SOI power transistors) and reducing temperatures in the semiconductor components by utilizing the thermoelectric cooling concept. The SOI transistor may be surrounded by a thermoelectric cooler (TEC) that laterally transports the heat away from the SOI transistor. The TEC includes a first electrode proximate the SOI transistor and a second electrode located away from the SOI transistor (and from the first electrode). Moreover, the TEC includes a portion of the semiconductor layer of the SOI substrate disposed between the first electrode and the second electrode, where a plurality of cavities (e.g., an array of through-silicon holes) is formed. Individual cavities (e.g., holes) may extend throughout the semiconductor layer and stop on the dielectric layer.

The portion of the semiconductor layer including the array of through-silicon holes (which may be referred to as a holey silicon or a holey silicon structure) functions as a thermoelectric cooler (TEC) in conjunction with the first and second electrodes under appropriate bias conditions—e.g., when activated by applying a bias to the first electrode with respect to the second electrode. Trench etch process or modified trench etch process can be used to create the array of through-silicon holes in the semiconductor layer of the SOI substrate. In some examples, the through-silicon holes may be filled with a dielectric material (or other suitable materials). The through-silicon holes filled with a dielectric material may modify thermal transfer characteristics of the portion of the semiconductor layer (e.g., the holey silicon structure)—e.g., to facilitate transferring of the heat away from the SOI transistor. Moreover, the semiconductor layer may include n-type dopants (e.g., arsenic, phosphorus) or p-type dopants (e.g., boron).

The TEC (e.g., a first electrode, a holey silicon structure with an array of trenches/holes, a second electrode) may surround one or more SOI-based devices—e.g., laterally-diffused metal-oxide-semiconductor (LDMOS) transistors. In some examples, an array of SOI power devices (e.g., a power device array) may be formed with individual SOI power devices surrounded by respective holey silicon structures (e.g., TECs). One or more TECs can be selectively activated so as to reduce temperatures of one or more power devices (e.g., cool down individual power devices) in the power device array fabricated in the SOI substrate, thereby improving temperature uniformity throughout the array of power devices and/or reducing overall temperatures of the array of power devices. In some examples, a pre-cooling sequence (or duration) may be applied prior to turning on (activating) the LDMOS transistors—e.g., to further enhance temperature reduction.

By dynamically turning on the TECs at one or multiple locations by controlling current/voltage pulses (with pre-cooling durations in some cases) applied to the TECs, temperatures in the power device array can be reduced. In this manner, the overall temperature throughout the power device array can be reduced, for example, lower than a temperature critical for safely operating the power device array—e.g., Tcrit that may trigger thermal runaway resulting in a permanent device failure. Accordingly, the TECs mitigate the challenges associated with the SOI substrate stemming from its inferior heat dissipation characteristics such that power devices can be built in the SOI substrate for high power applications, for example, high power applications including transient events.

Various examples are described subsequently. Although the specific examples may illustrate various aspects of the above generally described features, examples may incorporate any combination of the above generally described features (which are described in more detail in examples below).

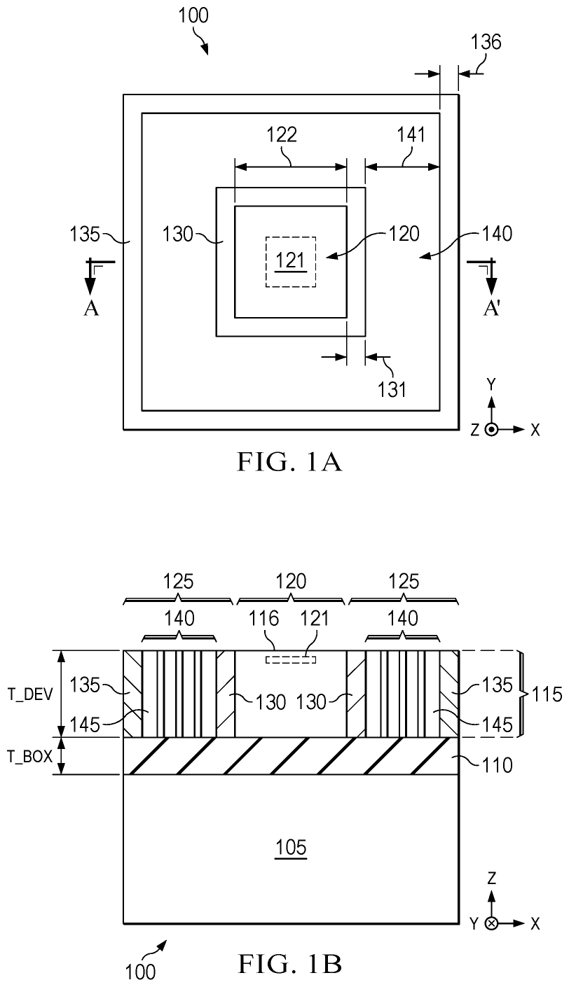

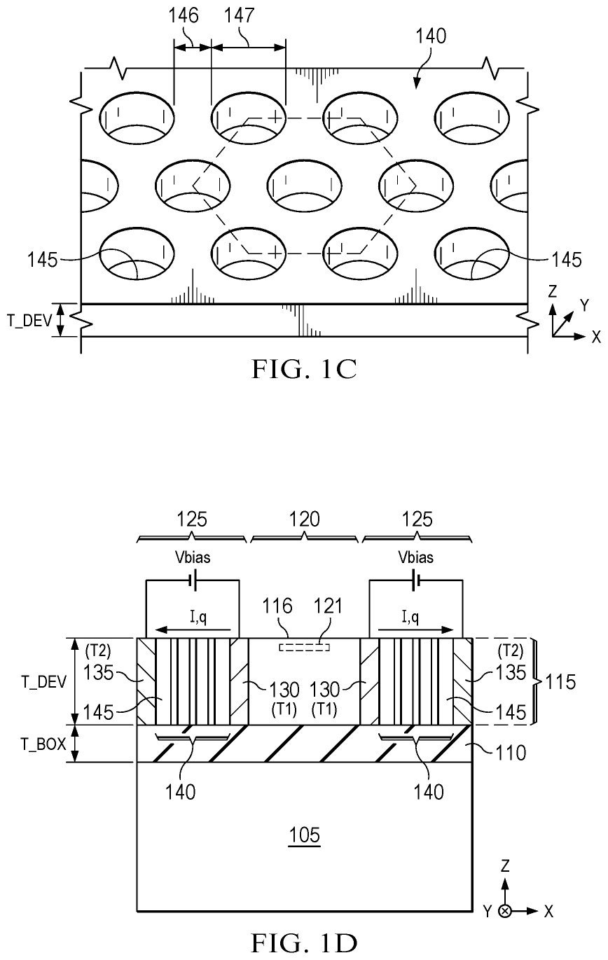

FIGS. 1A through 1D illustrate aspects of a semiconductor device with a thermoelectric cooler in an example of the description. FIG. 1A illustrates a plan view of a semiconductor device 100. FIG. 1B illustrates a cross-sectional view of the semiconductor device 100 across a line AA′ as marked in FIG. 1A. The semiconductor device 100 includes a substrate 105 (e.g., a bulk silicon), a dielectric layer 110 on the substrate 105, and a semiconductor layer 115 on the dielectric layer 110, which may be also be referred to as an epitaxial layer, an epi-layer, a device layer, or the like. In some examples, the dielectric layer 110 has a thickness (denoted as T_BOX in FIG. 1B) ranging between 0.1 μm to 20 μm. In some examples, the semiconductor layer 115 has a thickness (denoted as T_DEV in FIG. 1B) ranging between 30 μm and 300 μm. In other examples, the semiconductor layer 115 has a thickness less than 30 μm. The semiconductor layer 115 may include n-type or p-type dopants. In some examples, the semiconductor layer 115 has a p-type (or n-type) doping concentration ranging between 1×10¹⁸ cm⁻³ and 1×10²¹ cm⁻³.

Moreover, the semiconductor device 100 includes a first region 120 of the semiconductor layer 115 where one or more semiconductor components are located. The one or more semiconductor components generates heat during their operation. The first region has a dimension 122. In some examples, the dimension 122 (e.g., a width) ranges between approximately 10 μm and 500 μm. In some examples, the one or more semiconductor components include a laterally-diffused metal-oxide-semiconductor (LDMOS) transistor having a hot spot 121. In some examples, the hot spot 121 may have a size ranging between approximately 1 μm and 100 μm. In other examples, the hot spot 121 has a size less than 1 μm. The hot spot 121 may correspond to a channel region of a transistor (e.g., the LDMOS transistor) where intense power dissipation may occur, creating a local hot spot (e.g., the hot spot 121).

The semiconductor device 100 includes a first electrode 130 that laterally surrounds the first region 120 (which may also be referred to as a device region) of the semiconductor layer 115 as shown in FIG. 1A. The first electrode 130 extends from a plane coplanar with a surface 116 of the semiconductor layer 115 to the dielectric layer 110 as shown in FIG. 1B. The first electrode 130 has a width 131. In some examples, the first electrode 130 includes a conductive material, such as silicide (e.g., tungsten silicide, titanium silicide, cobalt silicide, nickel silicide), tungsten, aluminum, copper, titanium, tantalum, or a suitable electrically conductive material available in a semiconductor manufacturing environment. The semiconductor device 100 includes a second region 140 of the semiconductor layer 115 that laterally surrounds and contacts the first electrode 130. The second region 140 has a width 141 as shown in FIG. 1A—e.g., a shortest distance between the first electrode 130 and the second electrode 135.

Moreover, the semiconductor device 100 includes a second electrode 135 that laterally surrounds and contacts the second region 140 of the semiconductor layer 115 as shown in FIG. 1A. The second electrode 135 has a width 136. As with the first electrode 130, the second electrode 135 extends from a plane coplanar with the surface 116 of the semiconductor layer 115 to the dielectric layer 110 as shown in FIG. 1B. In some examples, the second electrode 135 includes a conductive material, such as silicide (e.g., tungsten silicide, titanium silicide, cobalt silicide, nickel silicide), tungsten, aluminum, copper, titanium, tantalum, or a suitable electrically conductive material available in a semiconductor manufacturing environment. In some examples, the first and second electrodes 130, 135 include a same conductive material. In some examples, the first and second electrodes 130, 135 include different conductive materials.

The second region 140 of the semiconductor layer 115 includes a plurality of cavities 145 (e.g., holes, orifices, pores) as shown in FIG. 1B. Each cavity 145 extends from a plane coplanar with the surface 116 of the semiconductor layer 115 to the dielectric layer 110 as shown in FIG. 1B. In some examples, one or more cavities 145 may have a footprint (e.g., a cross-sectional area in a plane parallel to the surface 116 of the semiconductor layer 115) of a circle, a rectangle, or an obround shape.

FIG. 1C illustrates a perspective view of a portion of the second region 140 (e.g., a holey silicon region). In the example of FIG. 1C, the second region 140 includes holes 145. As described above, each hole 145 extends through the semiconductor layer 115—e.g., through the thickness T_DEV as shown in FIG. 1C (and FIG. 1B). A distance 146 between the holes 145 may be referred to as a neck distance. In some examples, the holes 145 may be arranged (e.g., closely packed) to form a hexagon from a plan view as marked with a dotted line in FIG. 1C. In some examples, the holes 145 are filled with one or more dielectric materials. Overall distribution of holes 145 (e.g., an areal density of the holes 145) may determine porosity of the second region 140 of the semiconductor layer 115—e.g., a ratio between a total volume of the cavities and a volume of the semiconductor layer 115 where the cavities are distributed. In some examples, the porosity of the second region 140 of the semiconductor layer 115 may vary between approximately 10% to 70%.

Various parameters associated with the second region 140 of the semiconductor layer 115 (e.g., the holey silicon structure) may be determined to obtain desirable thermal and electrical characteristics of the TEC 125. Such parameters may include T_DEV, n-type or p-type doping concentration, neck distance 146 between the holes 145, diameter 147 of the hole 145, porosity, dielectric material(s) filling the holes 145, width 141 of the second region 140 (e.g., a width of the holey silicon region surrounding the hot spot), or the like. In some examples, the second region 140 of the semiconductor layer 115 may have the in-plane thermal conductivity of approximately 0.5 W/mK to 2 W/mK. In some examples, the second region 140 of the semiconductor layer 115 may have the cross-plane thermal conductivity of approximately 5 W/mK to 25 W/mK. In some examples, the second region 140 of the semiconductor layer 115 may have effective electrical conductivity of approximately 5×10³ S/m to 5×10⁴ S/m.

FIG. 1D illustrates the semiconductor device 100 during operation. Namely, an electrical bias (Vbias as shown in FIG. 1D) is applied to the first electrode 130 with respect to the second electrode 135. As a result of applying the electrical bias, current (denoted as I in FIG. 1D) flows from the first electrode 130 to the second electrode 135. In some examples, the current flow establishes a temperature gradient between the first electrode 130 and the second electrode 135—e.g., due to the Peltier effect triggered at the metal-semiconductor junctions. In other words, the temperature T1 at the first electrode 130 may be less than the temperature T2 at the second electrode 135. As such, the first electrode 130 may be referred to as a Peltier cooler (a cooler electrode, a cooler terminal) while the second electrode 135 may be referred to a Peltier heater (a heater electrode, a heater terminal).

As a result of applying the electrical bias, heat (denoted as q in FIG. 1D) flows from the first electrode 130 to the second electrode 135 as shown in FIG. 1D. In this manner, the TEC 125 may transport the thermal energy emanated from the hot spot 121 (through the cooler first electrode 130 located proximate the hot spot 121) to a location away from the hot spot 121. In other words, the cooler environment provided by the first electrode 130 of the TEC 125, which surrounds the hot spot 121, facilitates reducing the temperature of the hot spot 121. Accordingly, the heat transport may be regarded as pushing out the heat from the hot spot 121 toward a peripheral region surrounding the hot spot 121—e.g., toward the second electrode 135 through the second region 140.

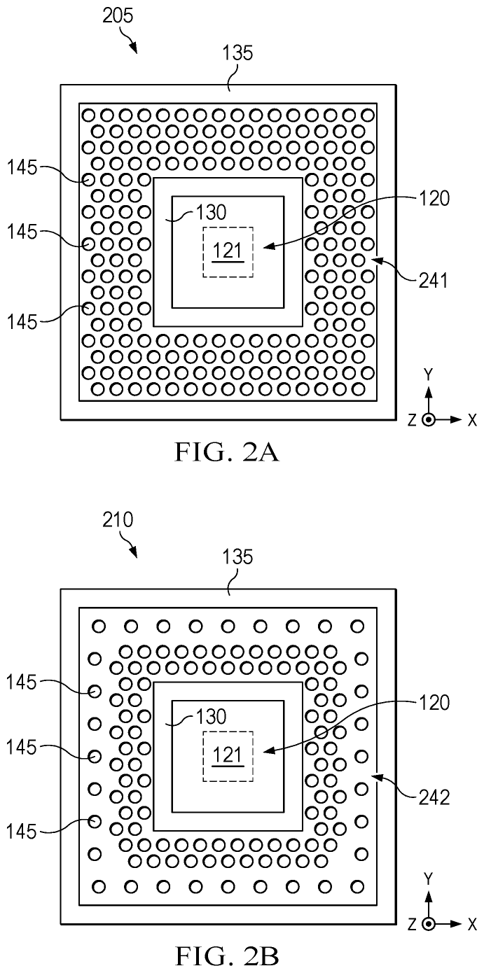

FIGS. 2A and 2B illustrate plan view diagrams of semiconductor devices with thermoelectric coolers in examples of the description. FIG. 2A shows a semiconductor device 205 that includes aspects of the semiconductor device 100—e.g., the device region 120 including the hot spot 121, the first and second electrodes 130, 135. The semiconductor device 205 includes the holey silicon region 241 located between the first and second electrodes 130, 135. The holey silicon region 241 includes an array of holes 145. Moreover, the first and second electrodes 130, 135 are in contact with the holey silicon region 241 at respective locations, thus forming metal-semiconductor junctions—e.g., a cooler junction at the interface between the first electrode 130 and the holey silicon region 241, a warmer junction at the interface between the second electrode 135 and the holey silicon region 241. The holey silicon region 241 of the semiconductor device 205 includes holes 145 with a uniform areal density (and porosity), a same size (a same diameter), a same neck distance.

In other examples, holey silicon regions may have different configurations than the holey silicon region 241 of FIG. 2A. For example, FIG. 2B illustrates a semiconductor device 210 that includes aspects of the semiconductor device 100—e.g., the device region 120 including the hot spot 121, the first and second electrodes 130, 135. The semiconductor device 210 includes the holey silicon region 242 located between the first and second electrodes 130, 135. The holey silicon region 242 is illustrated to have holes with varying areal densities—e.g., a greater density of holes (greater porosity) near the first electrode 130 and a less density of holes (less porosity) near the second electrode 135 as shown in FIG. 2B. In some examples, the holey silicon region 242 may include a greater density of holes (greater porosity) near the second electrode 135 and a less density of holes (less porosity) near the first electrode 130. In some examples, the holes may have different sizes (diameters) or different distances between them.

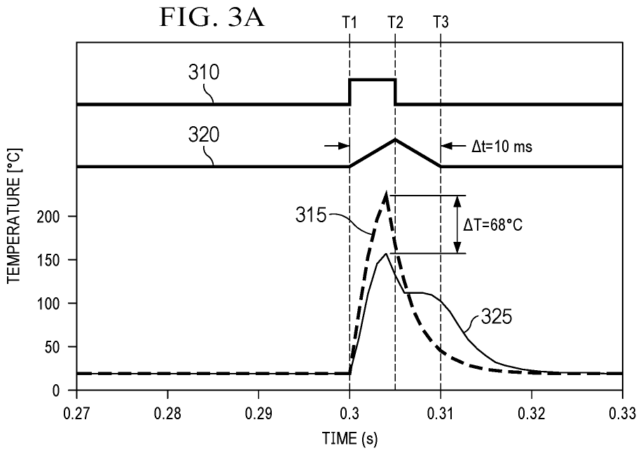

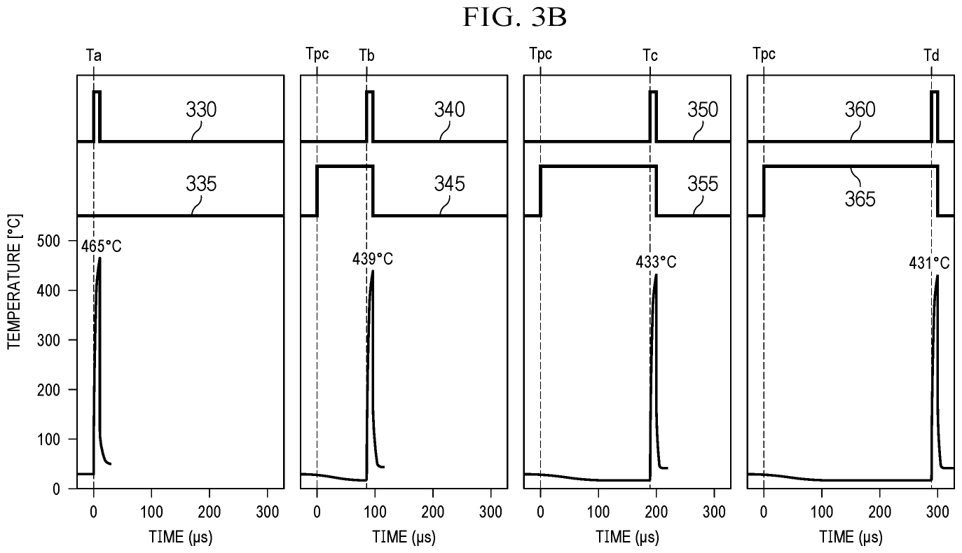

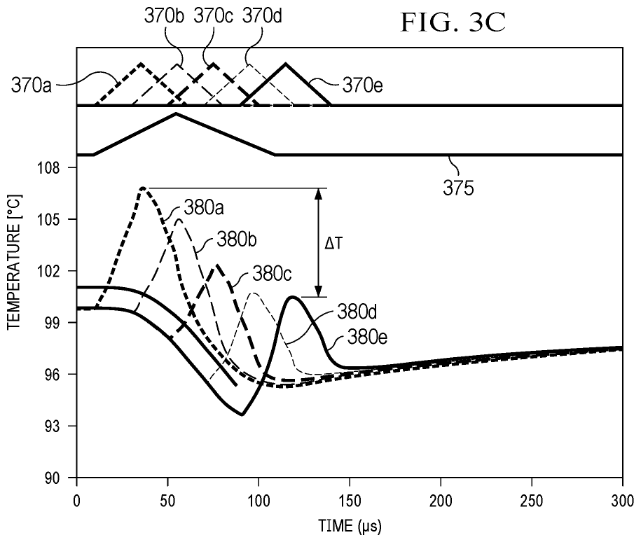

FIGS. 3A through 3C illustrate diagrams of operating characteristics of a semiconductor device with a thermoelectric cooler in examples of the description.

FIG. 3A illustrates electrical pulses (or signals) 310 and 320 as functions of time with the horizontal axis of FIG. 3A representing time in seconds. The electrical pulse 310 (e.g., voltage pulse, current pulse) may be an electrical pulse applied to one or more semiconductor components (e.g., an LDMOS transistor) in the device area 120 of the semiconductor device 100 (or the semiconductor device 205, 210), which may be referred to as an LDMOS pulse. The electrical pulse 320 (e.g., voltage pulse, current pulse) may be an electrical pulse applied to the TEC 125 (e.g., Vbias depicted in FIG. 1D), which may be referred to as a TEC pulse. Further illustrated in FIG. 3A are temperature profiles 315 and 325 as functions of time.

For example, an LDMOS transistor in the device area 120 may turn on at time T1 and turns off at time T2 as a result of applying the LDMOS pulse 310 to the LDMOS transistor. The temperature profile 315 may represent the temperature at or near the hot spot 121 (e.g., channel region of the LDMOS transistor) without activating the TEC 125. The temperature profile 315 may exceed 200° C. while the LDMOS transistor operates in response to the LDMOS pulse 310.

In contrast, the temperature profile 325 may represent the temperature at or near the hot spot 121 (e.g., channel region of the LDMOS transistor) with the TEC 125 activated, namely by applying the TEC pulse 320 to the TEC 125—e.g., applying Vbias using the TEC pulse to the TEC as described with reference to FIG. 1D. More specifically, the TEC pulse 320 is applied to the TEC 125 approximately at the time T1 when the LDMOS pulse 310 is applied to the LDMOS transistor. As a result of activating the TEC 125, the peak temperature of the temperature profile 325 is reduced significantly below 200° C. The peak temperature difference with and without applying the TEC pulse 320 to the TEC 125 may be approximately 68° C. as shown in FIG. 3A.

FIG. 3B illustrates effects of activating a TEC (e.g., TEC 125) prior to activating an LDMOS transistor in a device region 120. For example, LDMOS pulses 330, 340, 350, 360 represent electrical (e.g., voltage or current) pulses applied to the LDMOS transistor at time Ta, Tb, Tc, and Td, respectively. Durations of the LDMOS pulses 330, 340, 350, 360 are approximately the same. Various results described below show benefits of activating the TEC prior to activating the LDMOS transistor—e.g., pre-cooling effect. In some examples, the cooling flux generated by the TEC (e.g., the cooler temperature established at the first electrode 130 or the Peltier cooler electrode 130) may take time to diffuse to the hot spot 121. As such, a pre-cooling may be applied to overcome the delay associated with the diffusion of the cooling flux in rapid thermoelectric cooling environments—e.g., activating the TEC 125 ahead of activating the LDMOS transistor.

TEC pulse 335 in conjunction with the LDMOS pulse 330 represents a first condition where the TEC is not activated (e.g., the TEC pulse 335 being flat) when the LDMOS pulse 330 is applied at time Ta. FIG. 3B illustrates that the peak temperature (e.g., the hot spot temperature of the LDMOS transistor) may reach 465° C. under the first condition.

TEC pulse 345 in conjunction with the LDMOS pulse 340 represents a second condition where the TEC is activated at time Tpc when the LDMOS pulse 340 is applied at later time Tb. More specifically, the TEC 125 is activated slightly less than 100 us prior to activating the LDMOS transistor. FIG. 3B illustrates that the peak temperature (e.g., the hot spot temperature of the LDMOS transistor) may reach 439° C. under the second condition-hence, 26° C. cooler than the first condition.

TEC pulse 355 in conjunction with the LDMOS pulse 350 represents a third condition where the TEC is activated at time Tpc when the LDMOS pulse 350 is applied at later time Tc. More specifically, the TEC 125 is activated slightly less than 200 us prior to activating the LDMOS transistor. FIG. 3B illustrates that the peak temperature (e.g., the hot spot temperature of the LDMOS transistor) may reach 433° C. under the third condition-hence, 32° C. cooler than the first condition.

TEC pulse 365 in conjunction with the LDMOS pulse 360 represents a fourth condition where the TEC is activated at time Tpc when the LDMOS pulse 360 is applied at later time Td. More specifically, the TEC 125 is activated slightly less than 300 us prior to activating the LDMOS transistor. FIG. 3B illustrates that the peak temperature (e.g., the hot spot temperature of the LDMOS transistor) may reach 431° C. under the fourth condition-hence, 34° C. cooler than the first condition. As shown in FIG. 3B, the pre-cooling effect (e.g., by activating a TEC prior to activating a semiconductor device surrounded by the TEC) may facilitate reducing a peak temperature of the semiconductor device during operation.

FIG. 3C also illustrates effects of activating a TEC (e.g., TEC 125) prior to activating a semiconductor device (e.g., an LDMOS transistor) in a device region 120—e.g., a pre-cooling effect. For example, LDMOS pulses 370a through 370e represent electrical (e.g., voltage or current) pulses applied to the LDMOS transistor at different times with respect to a TEC pulse 375 applied to the TEC 125. Various results described below illustrate benefits of activating the TEC (e.g., pre-cooling) prior to activating the LDMOS transistor—e.g., compensating the delay associated with the cooling flux diffusion as described above.

For example, the LDMOS pulse 370a represents a condition where the TEC is activated approximately at time when the LDMOS pulse 370a is applied. As described with reference to FIG. 3A, concurrently activating the TEC is expected to reduce a peak temperature of the semiconductor device (e.g., LDMOS transistor) when compared to a peak temperature without activating the TEC. The temperature profile 380a associated with the LDMOS pulse 370a, however, shows that the reduction in the peak temperature is relatively less than other conditions where the TEC pulse 375 precedes the LDMOS pulses—e.g., LDMOS pulses 370b through 370e. For example, the LDMOS pulse 370c and associated temperature profile 380c shows the desired peak temperature reduction can be more significant when the TEC pulse 375 precedes the LDMOS pulse 370c—e.g., activating the TEC prior to activating the LDMOS transistor. As described with reference to FIGS. 3A through 3C, a TEC pulse may include a rectangular pulse, a triangular pulse, as well as any other pulse shapes devised to reduce the peak temperature (e.g., a sawtooth pulse, a staircase-shaped pulse), or a combination thereof.

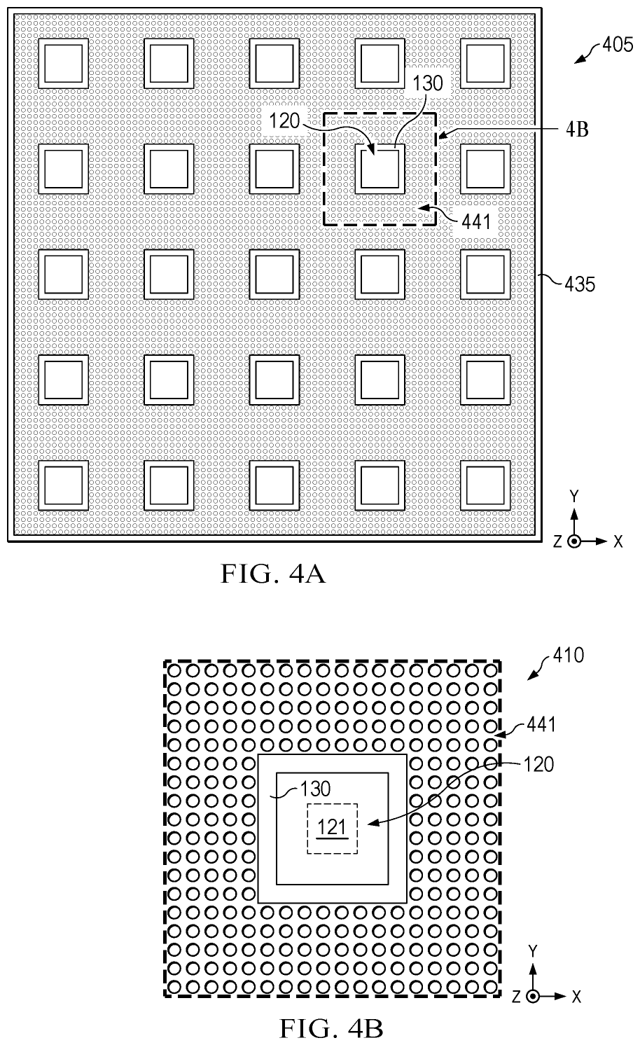

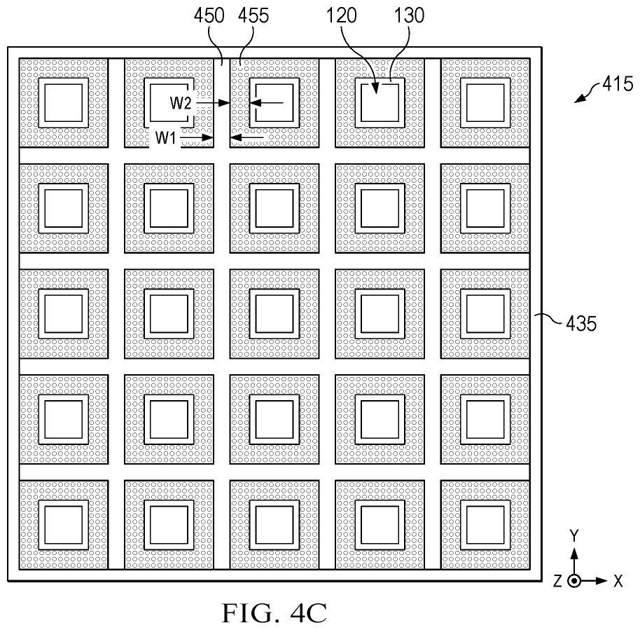

FIGS. 4A through 4C illustrate aspects of arrays of semiconductor devices with thermoelectric coolers in examples of the description. FIG. 4A shows a semiconductor device 405 including an array of a semiconductor device 410 of FIG. 4B. The semiconductor device 410 includes aspects of the semiconductor device 100 (or the semiconductor devices 205, 210).

The example semiconductor device 405 of FIG. 4A includes a total of twenty-five (25) semiconductor devices 410 arranged in a 5×5 array fashion. FIG. 4B shows a single semiconductor device 410 including the device region 120 with the hot spot 121, the first electrode 130 laterally surrounding the device region 120, and the holey silicon region 441 laterally surrounding and contacting the first electrode 130. Although the semiconductor device 410 of FIG. 4B is illustrated to have the holey silicon region 441 with a uniform porosity throughout (e.g., a uniform areal density of holes), the description is not limited thereto. For example, the holey silicon region 441 may have gradually decreasing density of holes as a distance from the first electrode 130 increases. In other examples, the holey silicon region 441 may have gradually increasing density of holes as a distance from the first electrode 130 increases.

A difference in individual semiconductor devices 410 of the array of semiconductor devices in comparison to the semiconductor device 100 is that the second electrode 135 of the semiconductor device 100 is omitted in each of the individual semiconductor devices 410. Instead, a second electrode 435 laterally surrounds the entire array of the semiconductor devices 410 as shown in FIG. 4A. The second electrode 435 may be regarded as a common electrode (e.g., a common Peltier heater electrode) in conjunction with individual first electrodes 130 of the semiconductor devices 410. In this manner, the areal efficiency of the semiconductor device 405 (e.g., the array of semiconductor devices 410) may be improved—e.g., when compared with a similar array of the semiconductor device 100, each semiconductor device 100 having its own second electrode 135. As shown in FIG. 4A, each one of the device regions 120 in the array is laterally surrounded with a TEC including a Peltier cooler electrode (e.g., the respective first electrode 130) proximate the hot spot 121 as well as a Peltier heater electrode (e.g., the common second electrode 435) located away from the respective hot spot 121.

In other words, the semiconductor device 405 includes an array of first electrodes 130 (e.g., a total of twenty-five (25) first electrodes 130 arranged in a 5×5 array fashion), and each of the first electrode 130 laterally surrounds a respective first region (e.g., the device region 120) of the semiconductor layer (e.g., the semiconductor layer 115). The semiconductor device 405 also includes a second region (e.g., the holey silicon region 441) of the semiconductor layer laterally surrounding and contacting each of the first electrode 130 of the array. Moreover, the semiconductor device 405 includes a second electrode (e.g., the second electrode 435) laterally surrounding and contacting the second region 441 of the semiconductor layer.

In some examples, each one of the first region (e.g., the device regions 120) of the semiconductor layer includes one or more semiconductor devices (e.g., laterally-diffused metal-oxide-semiconductor (LDMOS) transistors). Each of the first electrodes 130 may extend from a plane coplanar with a surface of the semiconductor layer to a dielectric layer—e.g., the dielectric layer 110 described with reference to FIG. 1B. Also, the second electrode may extend from the plane to the dielectric layer. The second region (e.g., the holey silicon region 140) of the semiconductor device 405 includes a plurality of cavities, and each cavity of the plurality may extend from the plane coplanar with the surface of the semiconductor layer to the dielectric layer.

FIG. 4C illustrates a semiconductor device 415 as an alternative implementation of the semiconductor device 405 of FIG. 4A. As with the semiconductor device 405, the semiconductor device 415 includes a 5×5 array of individual semiconductor devices (e.g., the semiconductor devices 410 of FIG. 4B). A difference in the semiconductor device 415 in comparison to the semiconductor device 405 is that the semiconductor layer disposed between the first electrodes 130 and the second electrode 435 includes a first region 450 distributed throughout the semiconductor device 415 as shown in FIG. 4C. The first region 450 has a first width denoted as “W1” in FIG. 4C. Also, a second region 455 (e.g., the holey silicon region) of the semiconductor layer located between the first region 450 and individual Peltier cooler electrodes (e.g., the first electrodes 130) has a second width denoted as “W2” in FIG. 4C. In some examples, the first region 450 includes no holes (e.g., holes 145). Namely, the first region 450 may be devoid of holes (or cavities) in such examples. In other examples, the first region 450 may include holes with a lesser areal density than the second region 455—e.g., the first region 450 with an areal density that is less than the areal density of holes proximate the first electrodes 130. In some examples, the first and second widths (W1 and W2) may be determined to obtain desirable thermal and electrical characteristics of the semiconductor device 415. In some examples, having varying areal densities of holes may mitigate certain semiconductor processing complexities associated with forming the holes (e.g., trench etch process) throughout an extended area of the semiconductor layer.

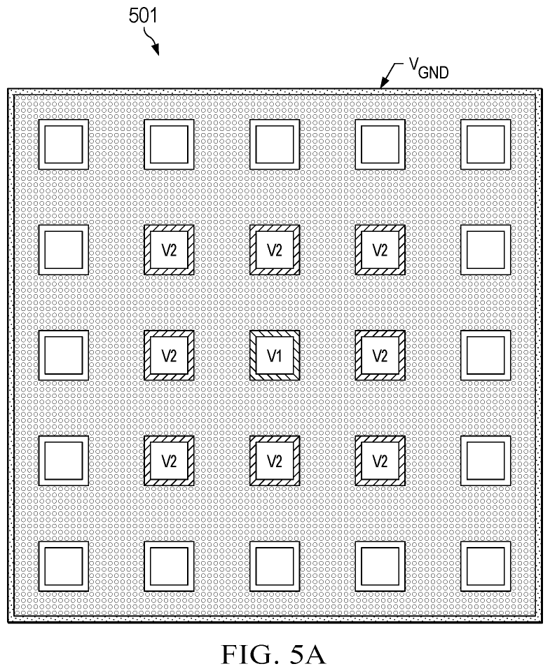

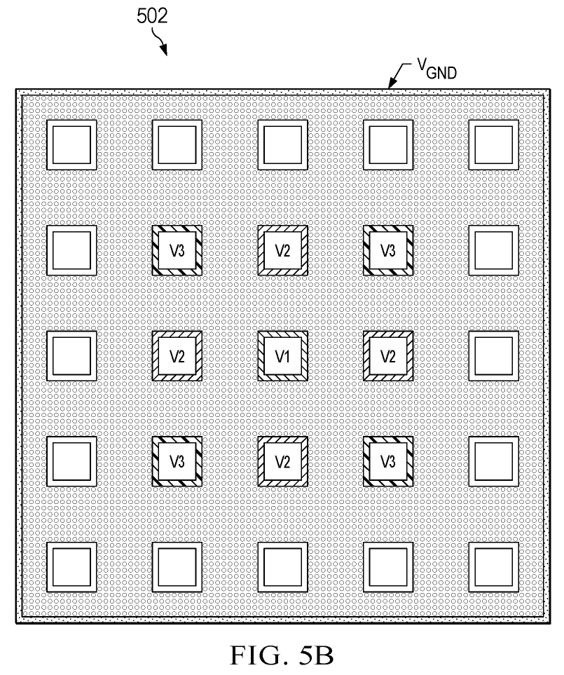

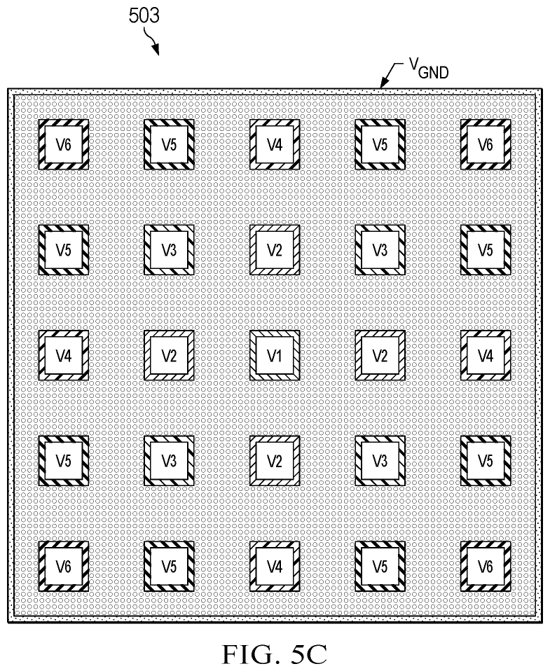

FIGS. 5A through 5C illustrate diagrams of operating characteristics of an array of semiconductor devices with thermoelectric coolers (e.g., the semiconductor device 405 described with reference to FIG. 4A) in examples of the description. FIGS. 5A through 5C illustrate multi-level selective activation of the TECs of the semiconductor device 405—e.g., by selectively applying one or more Vbias to the first electrodes 130 of the array. In the examples of FIGS. 5A through 5C, selected (activated) first electrodes 130 are cross-hatched with different patterns corresponding to different voltages (e.g., V1 through V6). Cross-hatched patterns are absent for unselected (un-activated) first electrodes 130. The common second electrode 435 remains at a ground potential (e.g., VGND).

Selectively activating different portions of the TECs of the semiconductor device 405 by selectively applying different voltages to the array of the first electrodes 130 can reduce the peak/maximum temperature as well as overall temperature distribution of the semiconductor device 405. In some examples, effects of activating a first electrode 130 in the array of first electrodes 130 may be regarded as “pushing the heat away” from the target device area 120 associated with the activated first electrode 130. In other words, cooling down the target device area 120 may transfer the heat to the surrounding areas. The surrounding areas may be cooled down by transferring the heat to the next surrounding areas toward the outer boundary of the semiconductor device 405. In other words, the overall heat transfer can be devised to occur toward the common second electrode 435 located laterally away from the array of device areas 120 by determining different voltages applied to the first electrodes 130 as described in more detail below.

For example, FIG. 5A shows a first biasing pattern 501 such that the first electrode located at the center (the center electrode, the center TEC) is biased at V1, and the first electrodes next to (around) the center electrode are biased at V2 that is less than V1. The rest of first electrodes are not biased (un-activated). The peak temperature of the semiconductor device 405 under the first biasing pattern 501 is less than the peak temperature associated with activating none of the TECs (e.g., a baseline biasing pattern) by about 22° C. Moreover, a peak-to-peak distribution of the temperature (e.g., a difference between the hottest temperature and the coolest temperature) within the semiconductor device 405 is reduced from about 67° C. (under the baseline biasing pattern) to about 40° C. (under the first biasing pattern 501).

FIG. 5B shows a second biasing pattern 502 such that the first electrode located at the center (the center electrode, the center TEC) is biased at V1, and the first electrodes vertically or horizontally adjacent to the center electrode are biased at V2 that is less than V1. Moreover, the first electrodes diagonally adjacent to the center electrode are biased at V3 that is less than V2. In other words, V2 and V3 are determined based on distances of corresponding first electrodes from the center electrode. The rest of first electrodes are not biased (un-activated). The peak temperature of the semiconductor device 405 under the second biasing pattern 502 is less than the peak temperature of the baseline biasing pattern by about 27° C. Moreover, a peak-to-peak distribution of the temperatures (e.g., a difference between the hottest temperature and the coolest temperature) within the semiconductor device 405 is reduced from about 67° C. (under the baseline biasing pattern) to about 35° C. (under the second biasing pattern 502).

FIG. 5C shows a third biasing pattern 503 such that the first electrode located at the center (the center electrode, the center TEC) is biased at V1, and the rest of the first electrodes are biased based on their distances from the center electrode, namely V2 less than V1, V3 less than V2, V4 less than V3, V5 less than V4, and V6 less than V5. All of the first electrodes are biased (activated). The peak temperature of the semiconductor device 405 under the third biasing pattern 503 is less than the peak temperature of the baseline biasing pattern by about 35° C. Moreover, a peak-to-peak distribution of the temperatures (e.g., a difference between the hottest temperature and the coolest temperature) within the semiconductor device 405 is reduced from about 67° C. (under the baseline biasing pattern) to about 10° C. (under the third biasing pattern 503).

In an n×n array where n is an integer greater than 1 (or an n×m array where n and m are integers, n being different than m), the voltage applied to the center electrode (or central first electrodes located in a central area of the array) may be the greatest with the voltage(s) applied to the rest of first electrodes gradually decreasing based on their distances from the center electrode (or central electrodes). In other words, the voltages may be devised to gradually (or successively) decrease toward the cooler electrodes located at the edge or corner of the array. Moreover, although the cooling effect may be proportional to the applied voltages (e.g., the greater the voltage, the stronger the cooling effect), there may be a balance between Peltier cooling and Joule heating (due to the current flow through the holey silicon region) that needs to be maintained.

Examples of the description have been described above by way of example only and not limitation. Numerous changes to the examples can be made in accordance with the description without departing from the spirit or scope of the description. For example, although examples described above with reference to FIGS. 4A through 5C include a 5×5 array of semiconductor devices 410, the description is not limited thereto. In some examples, a semiconductor device may include 1×2 array, 1×3 array, 2×2 array, 3×3 array, even 10×20 array, among others. Also, although the example semiconductor devices (e.g., the semiconductor devices 100, 205, 210, 410) has a square shape, the description is not limited thereto. For example, the semiconductor device including TEC may have a rectangular shape, a pentagon shape, a hexagonal shape, or any polygon shapes. In some cases, LDMOS transistors (or a semiconductor component subjected to the risk of the self-heating during operation) may have a circular shape or a shape resembling a racetrack. Accordingly, the semiconductor device with TEC surrounding the LDMOS transistor may have a circular shape or a racetrack shape in such cases. In addition to cooling the SOI transistors, the concept of TEC based on the holey silicon structure disclosed herein may be applied to other SOI-based semiconductor components, such as SOI FinFETs, SOI gate-all-around (GAA) FETs.

In addition, while in the illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above described implementations.

What is claimed is:

1. A semiconductor device, comprising:
a substrate including a dielectric layer and a semiconductor layer on the dielectric layer;
a first electrode laterally surrounding a first region of the semiconductor layer;
a second region of the semiconductor layer laterally surrounding and contacting the first electrode; and
a second electrode laterally surrounding and contacting the second region of the semiconductor layer.

2. The semiconductor device of claim 1, wherein the first region of the semiconductor layer includes one or more semiconductor components generating heat during operation.

3. The semiconductor device of claim 2, wherein the one or more semiconductor components include a laterally-diffused metal-oxide-semiconductor (LDMOS) transistor.

4. The semiconductor device of claim 1, wherein:
the first electrode extends from a plane coplanar with a surface of the semiconductor layer to the dielectric layer; and
the first electrode includes a conductive material surrounding the first region of the semiconductor layer.

5. The semiconductor device of claim 4, wherein the conductive material includes at least one of silicide, tungsten, aluminum, copper, titanium, and tantalum.

6. The semiconductor device of claim 1, wherein the second region of the semiconductor layer includes a plurality of cavities, each cavity of the plurality extended from a plane coplanar with a surface of the semiconductor layer to the dielectric layer.

7. The semiconductor device of claim 6, wherein one or more cavities of the plurality of cavities has a footprint of a circle, a rectangle, or an obround shape.

8. The semiconductor device of claim 6, wherein the second region of the semiconductor layer includes:
a first portion having a first plurality of cavities, the first plurality of cavities having a first areal density; and
a second portion having a second plurality of cavities, the second plurality of cavities having a second areal density different than the first areal density.

9. The semiconductor device of claim 1, wherein:
the second electrode extends from a plane coplanar with a surface of the semiconductor layer to the dielectric layer; and
the second electrode includes a conductive material contacting the second region of the semiconductor layer.

10. The semiconductor device of claim 9, wherein the conductive material includes at least one of silicide, tungsten, aluminum, copper, titanium, and tantalum.

11. A semiconductor device, comprising:
a substrate including a dielectric layer and a semiconductor layer on the dielectric layer;
an array of first electrodes, each of the first electrode laterally surrounding a respective first region of the semiconductor layer;
a second region of the semiconductor layer laterally surrounding and contacting each of the first electrode of the array; and
a second electrode laterally surrounding and contacting the second region of the semiconductor layer.

12. The semiconductor device of claim 11, wherein the each of the respective first region of the semiconductor layer includes one or more laterally-diffused metal-oxide-semiconductor (LDMOS) transistors.

13. The semiconductor device of claim 11, wherein:
each of the first electrodes extends from a plane coplanar with a surface of the semiconductor layer to the dielectric layer; and
the second electrode extends from the plane to the dielectric layer.

14. The semiconductor device of claim 11, wherein the second region of the semiconductor layer includes a plurality of cavities, each cavity of the plurality extended from a plane coplanar with a surface of the semiconductor layer to the dielectric layer.

15. A method, comprising:
applying an electrical bias to a first electrode laterally surrounding a first region of a semiconductor layer, the first region including one or more semiconductor components generating heat during operation; and
activating the one or more semiconductor components after applying the electrical bias to the first electrode, wherein:
the semiconductor layer is disposed on an oxide layer of a substrate;
a second region of the semiconductor layer laterally surrounding and contacting the first electrode; and
a second electrode laterally surrounding and contacting the second region of the semiconductor layer.

16. The method of claim 15, wherein electrical current flows from the first electrode to the second electrode as a result of applying the electrical bias.

17. The method of claim 15, wherein heat flows from the first electrode to the second electrode as a result of applying the electrical bias.

18. The method of claim 15, wherein the electrical bias includes a rectangular pulse, a triangular pulse, a sawtooth pulse, or a combination thereof.

19. The method of claim 15, further comprising:
maintaining the electrical bias while the one or more semiconductor components are activated.

20. The method of claim 15, further comprising:
terminating the electrical bias while the one or more semiconductor components are activated.
